(19) United States
(12) Patent Application Publication
(10) Pub. No.: US 2009/0304931 A1
(43) Pub. Date: Dec. 10, 2009

(54) MASK, DEPOSITION APPARATUS USING MASK, DEPOSITION METHOD USING MASK, AND DEVICE MANUFACTURING METHOD USING DEPOSITION APPARATUS

(75) Inventor: Takahide Uenosono, Tokyo (JP)

Correspondence Address: FITZPATRICK CELLA HARPER & SCINTO, 1290 Avenue of the Americas, NEW YORK, NY, 10104-3800, US

(73) Assignee: CANON ANELVA CORPORATION, Kawasaki-shi (JP)

(21) Appl. No.: 12/476,404

(22) Filed: Jun. 2, 2009

(30) Foreign Application Priority Data
Jun. 4, 2008 (JP) 2008-146701

(51) Int. Cl. B05D 5/00; C23C 16/44; B05C 11/00

(52) U.S. Cl. 427/282; 118/728; 118/504

(57) ABSTRACT

Four masks respectively corresponding to the four sides of a rectangular glass substrate are prepared. The four masks are set in a deposition chamber in a divisional state. When the masks are moved linearly on a plane flush with the glass substrate in directions perpendicular to the respective sides of the glass substrate, the divisional masks are connected to each other and form a mask as one assembly. At this time, the masks cover the periphery of the glass substrate entirely.

### BACKGROUND OF THE INVENTION

1. Field of the Invention

The present invention relates to a mask employed when processing the principal surface of a base substance, a deposition apparatus using the mask, a deposition method using the mask, and a device manufacturing method using the deposition apparatus.

2. Description of the Related Art

For example, a single-substrate-type magnetron sputtering apparatus is used as a deposition apparatus for a glass substrate, and the arrangement disclosed in Japanese Patent Laid-Open No. 2004-211133 is known as an example of the apparatus.

However, the apparatus disclosed in Japanese Patent Laid-Open No. 2004-211133 includes in a deposition chamber a mask having a size (area) equal to or larger than that of the glass substrate. The mask is exchanged when a predetermined number of glass substrates are processed, so films attached to the mask will not separate due to their increasing weights. This exchange operation, however, does not have sufficient operation efficiency due to the shape and weight of the mask.

### SUMMARY OF THE INVENTION

The present invention provides in order to solve the problem described above, a mask, a deposition apparatus using the mask, and a deposition method using the mask that can improve the operation efficiency of mask exchange.

The periphery of a base substance (or substrate) refers to part of a surface, of the surfaces of the base substance, on a side which is to undergo a process or an end face which is a side surface of the base substance.

According to one aspect of the present invention, there is provided a mask used for processing a plate-like base substance, comprising: a plurality of components which come into contact with a periphery of the base substance which is one of part of a surface, of surfaces of the base substances on a side which is to undergo a process, or an end face which is a side surface of the base substances wherein in the process, the plurality of components are connected -o each other at the periphery of the base substance and used as one assembly.

According to another aspect of the present invention, there is provided a deposition apparatus comprising: a deposition chamber; a base substance holder which is disposed in the deposition chamber and on which a plate-like base substance is to be placed; and the above-mentioned mask which is arranged in the deposition chamber for the base substance placed on the base substance holder.

According to the present inventions as the mask is divided unlike a conventional one-piece masks the individual components that form the mask are compact and light-weight, thus improving the exchange operation efficiency.

Further features of the present invention will become apparent from the following description of exemplary embodiments with reference to the attached drawings.

### BRIEF DESCRIPTION OF THE DRAWINGS

FIG. 1A shows a state (left side view) in which masks according to an embodiment of the present invention are placed on a base substance holder and a state (right side view) in which the masks are set on the periphery of a glass substrate;

FIG. 1B is a longitudinal sectional view in a state in which the masks cover the periphery of the glass substrate on the base substance holder;

FIGS. 2A and 2B are views for explaining masks as a modification of the embodiment of FIGS. 1A and 1B and a state in which the masks are set on the glass substrate;

FIGS. 3A and 3B are views for explaining masks as a modification of the embodiment of FIGS. 1A and 1B and a state in which the masks are set on the glass substrate;

FIG. 4 is a view for explaining masks as a modification of the embodiment of FIGS. 1A and 1B and a state in which the masks are set on the glass substrate; and

FIG. 5 is a schematic sectional view of a deposition apparatus according to the present invention.

### DESCRIPTION OF THE EMBODIMENTS

Embodiments of the present invention will be described with reference to the accompanying drawings. FIG. 5 is a view showing the schematic arrangement of a single-substrate-type magnetron sputtering apparatus. A base substance holder 2 including a heater is disposed in a deposition chamber 1. A glass substrate 3 as a base substance to be processed is placed on the base substance holder 2.

A mask 4 covering the periphery of the glass substrate 3 is mounted on the base substance holder 2.

Furthermore, a target 6 opposing the base substance holder 2 and serving as a negative electrode is disposed above the base substance holder 2. A magnet 7 which reciprocates is disposed on the rear side of the target 6. When the magnet 7 reciprocates, a predetermined magnetic field is formed on the surface of the target 6.

The interior of the deposition chamber 1 is filled with a sputtering gas, and plasma discharge is performed while reciprocating the magnet 7. Thus, deposition by sputtering is performed on the glass substrate 3. During the deposition, the mask 4 covers the periphery of the glass substrate 3, so no film is formed on the periphery of the glass substrate 3 by sputtering.

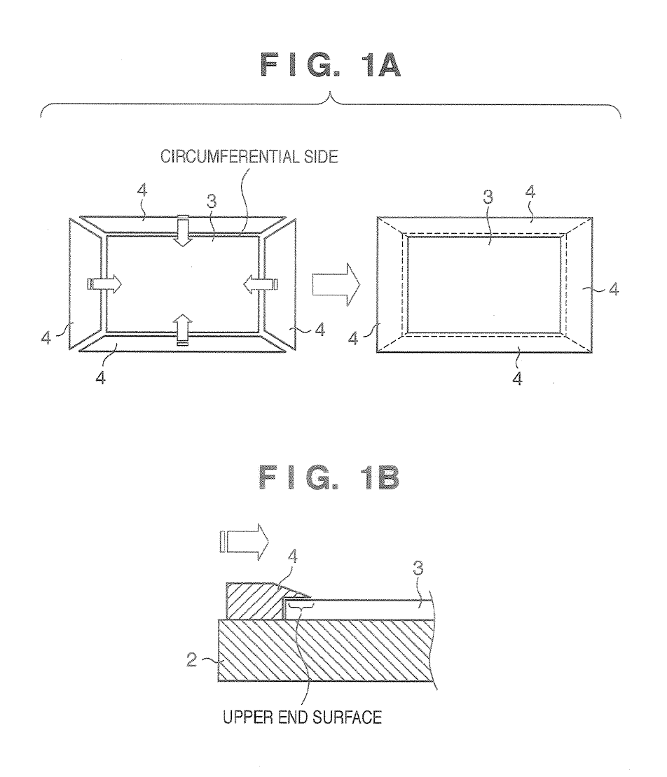

FIG. 1A shows a state (left side view) in which mask 4 according to an embodiment of the present invention are placed on a base substance holder 2 and a state (right side view) in which the mask 4 is set on the periphery of a glass substrate 3. FIG. 1B is a longitudinal sectional view in a state in which the mask 4 covers the periphery of the glass substrate 3 on the base substance holder 2. The periphery of a base substance refers to part (upper end surface) of a surface, among the surfaces of the base substance, on a side which is used to execute a process, or an end face (circumferential side) which is a side surface of the base substance.

In a deposition apparatus which uses the masks of this embodiment, a plurality of lift pins (not shown) move upward from, of the base substance holder 2 in the deposition chamber 1 of the deposition apparatus shown in FIG. 5, the surface which holds the glass substrate 3. An arm (not shown) sets the glass substrate 3 as the base substance to be processed on the lift pins. The lift pins are controlled to move downward while supporting the glass substrate 3 and place the glass substrate 3 on the base substance holder 2.

As shown in the left side view of FIG. 1A, four pieces of the mask 4 respectively corresponding to the four sides of the rectangular glass substrate 3 placed on the base substance holder 2 are prepared. Four pieces of the mask 4 are set in the deposition chamber 1 in a divisional state.

According to this embodiment, as shown in the left side view of FIG. 1A, each piece of the mask 4 is arranged near the corresponding sides of the glass substrate 3. After that, four pieces of the mask 4 are moved, as shown in the right side view of FIG. 1A, so they cover, as an assembly, the periphery of the glass substrate 3.

As far as the deposition apparatus can realize this layout of the mask 4 in terms of the capacity and performance, the divided mask 4 may be stored in the deposition chamber 1 in any state. For example, each piece of the mask 4 may be stored vertically with respect to the surface of the base substance holder 2, or four pieces of the mask 4 may be stored at one location.

The mask 4 can be moved using motor driving as well as hydraulic driving such as air pressure or oil pressure. Any driving method can be utilized. Each piece of the mask 4 is connected to such driving system via a support (not shown).

As shown in FIG. 1A, each piece of the mask 4 moves on a plane flush with the glass substrate 3, i.e., on the base substance holder 2, so four pieces of the mask 4 surround the periphery of the glass substrate 3 from four directions corresponding to the four circumferential sides of the glass substrate 3. At this time, each piece of the mask 4 moves linearly along directions perpendicular to the corresponding circumferential sides of the glass substrate 3.

As a result, four pieces of the mask 4 are connected to each other to form one assembly, thus forming a frame-like mask.

Assume that no film should be attached to any periphery of the glass substrate 3 in the post-process of the glass substrate 3. In this case, each piece of the mask 4 may employ a covering structure so it slightly spreads over the periphery of the corresponding side of the glass substrate 3. This can prevent any film from being attached to the periphery of the glass substrate 3.

With the covering structure, in deposition on the glass substrate 3, each piece of the mask 4 is in contact with the end faces (circumferential sides) of the periphery of the glass substrate 3 partly or entirely. Thus, the glass substrate 3 can be held.

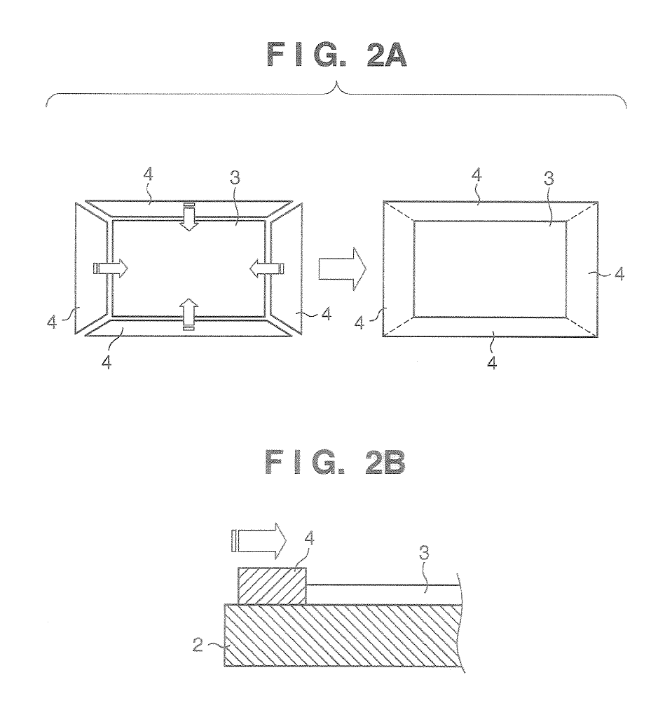

Assume that a film may be attached to the periphery of the glass substrate 3 in the post-process of the glass substrate 3. In this case, the mask 4 each not having a covering structure is employed. As shown in FIGS. 2A and 2B, the mask 4 is formed not to cover the ends of the upper end surface of the glass substrate 3. Four pieces of the mask 4 come close to the end faces (circumferential sides) of the glass substrate 3 to be in contact with them thereby fixing the glass substrate 3. In this case, the contact surfaces of the mask 4 and glass substrate 3 correspond to the end faces (circumferential sides), respectively, of the glass substrate 3

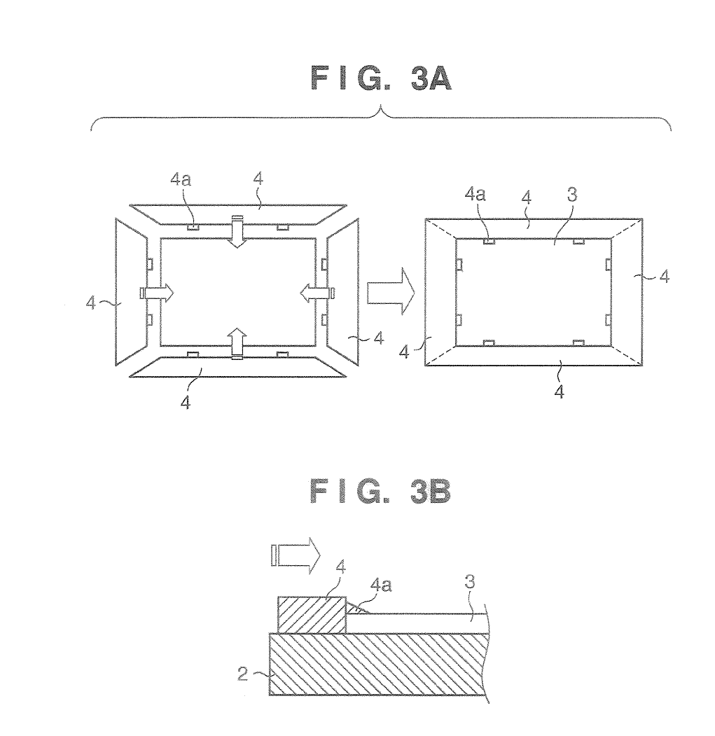

The divided mask 4 each having a shape identical to that shown in FIGS. 2A and 2B may be provided with pawl-shaped clamps 4a which partially cover the periphery of the glass substrate 3, as shown in FIG. 3B. The mask 4 with the clamps 4a enables deposition even when the base substance holder 2 stands upright vertically.

As the material of the mask 4 described above, SUS, Al, or the like is mainly used.

The shape of the mask 4 will be described hereinafter.

The mask 4 preferably have a shape obtained by dividing a frame surrounding the periphery of the rectangular glass substrate 3 into four portions to correspond to the four sides of the glass substrate 3. This is due to the following reasons. Upon application of equal forces to the end faces (circumferential sides) of the glass substrate 3 from four directions, the divided mask 4 can be stably formed into one assembly. Since the mask 4 comes into contact with the end faces (circumferential sides), the glass substrate 3 can be held.

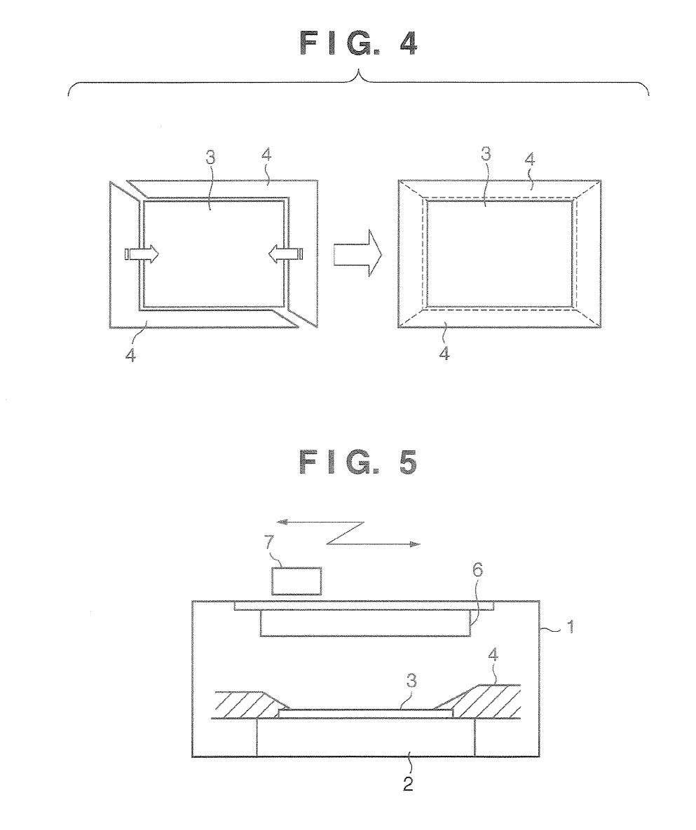

As the mask 4 having another shape, mask 4 as shown in FIG. 4 may be employed which have a shape obtained by halving a frame shape surrounding the periphery (circumferential sides) of the rectangular glass substrate 3 into two L-shaped portions. Namely, each piece of the mask 4 has a divisional shape corresponding to two adjacent sides of the four sides of the glass substrate 3.

Such an L-shaped mask 4 can have a weight half that of the frame-like mask. In addition, two driving systems suffice for moving the divided mask 4. Therefore, forces parallel and equal to each other can be exerted on the each piece of the mask 4, so that the divided mask 4 can be stably formed into one assembly.

A deposition method in a deposition apparatus using a mask according to the present invention will be described with reference to FIGS. 1A and 1B and FIG. 5.

First, in a deposition chamber 1 where a glass substrate 3 is placed, the divided mask 4 respectively corresponding to the four sides of the glass substrate 3 are arranged. This layout corresponds to the left side view of FIG. 1A.

After that, the mask 4 is moved linearly on a plane flush with the glass substrate 3 along directions perpendicular to the respective sides (circumferential sides) of the glass substrate 3. As a result, the covering structures of the divided mask 4 come into contact with the end faces of the periphery of the glass substrate 3 partly or entirely. Simultaneously, each piece of the mask 4 is connected to each other and forms a mask as one assembly. At this time, in FIG. 1A, the mask 4 cover the periphery of the glass substrate 3 entirely. The right side view of FIG. 1A, and FIG. 1B show this state.

After that, the interior of the deposition chamber 1 is evacuated to a reduced pressure, and deposition is performed on the glass substrate 3 the periphery of which is covered with the mask 4 that form one assembly.

Although this deposition step may employ sputtering as shown in FIG. 5, it is not limited to this deposition method.

In the deposition method described above, the masks shown in FIGS. 1A and 1B are employed. Alternatively the masks shown in FIGS. 2A and 2B to FIG. 4 can also be employed.

The deposition apparatus according to the embodiment of the present invention is applicable to a method of manufacturing an electronic device (to be merely referred to as a “device” as well hereinafter). This device manufacturing method has a deposition step which performs deposition in a deposition apparatus. Examples of the device include a plasma display panel (PDP) and liquid crystal panel. For example, in steps of forming an MgO protection film on a plasma display panel (PDP), a glass substrate is transported to a portion above a deposition source in a vacuum deposition apparatus as a deposition apparatus, and an MgO film is formed on the glass substrate. In this case, a mask having a predetermined shape is arranged on the peripheral portion or the like of the glass substrate which serves as an adhesion seal portion or wire connecting portion, so no thin film is formed there. Then, vapor deposition is performed. As a result, the plasma display panel can be provided with an arrangement necessary as a display device.

The masks described above by the embodiments are applicable not only to a base substance such as a glass substrate having four sides, but also to any plate-like base substance having a plurality of sides.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2008-146701, filed Jun. 4, 2008, which is hereby incorporated by reference herein in its entirety.

What is claimed is:

1. A mask used for processing a plate-like base substance, comprising:
a plurality of components which come into contact with a periphery of the base substance which is one of part of a surface, of surfaces of the base substance, on a side which is to undergo a process, or an end face which is a side surface of the base substance,
wherein in the process, said plurality of components are connected to each other at the periphery of the base substance and used as one assembly.

2. The mask according to claim 1, wherein
the base substance includes a rectangular substrate, and
said components are divided into portions respectively corresponding to four sides of the substrate.

3. The mask according to claim 1, wherein
the base substance includes a rectangular substrate, and
said components are divided into portions respectively corresponding to two adjacent sides of four sides of the substrate.

4. A deposition apparatus comprising:
a deposition chamber;
a base substance holder which is disposed in said deposition chamber and on which a plate-like base substance is to be placed; and
a mask according to claim 1 which is arranged in said deposition chamber for the base substance placed on said base substance holder.

5. The apparatus according to claim 4, wherein components that form said mask are movable toward corresponding circumferential sides of the base substance.

6. The apparatus according to claim 4, wherein physical vapor deposition is performed in said deposition chamber under a reduced pressure.

7. A deposition method using a mask, comprising:
an arranging step of arranging a mask according to claim 2 in a deposition chamber where a rectangular substrate is placed, such that the mask corresponds to four sides of the substrate;
a moving step of moving corresponding components toward the respective sides of the substrate along a plane flush with the substrate placed in the deposition chamber;
a forming step of forming the mask as one assembly by bringing the respective components into contact with a periphery of the substrate and connecting the respective components to each other; and
a deposition step of performing a deposition process for the substrate covered with the mask serving as one assembly.

8. A deposition method using a mask, comprising:
an arranging step of arranging a mask according to claim 3 in a deposition chamber where a rectangular substrate is placed, such that the mask corresponds to two adjacent sides of four sides of the substrate;
a moving step of moving corresponding components toward the two adjacent sides of the substrate along a plane flush with the substrate placed in the deposition chamber;
a forming step of forming the mask as one assembly by bringing the respective components into contact with a periphery of the substrate and connecting the respective components to each other; and
a deposition step of performing a deposition process for the substrate covered with the mask serving as one assembly.

9. The method according to claim 7, wherein in the deposition step, a deposition process by physical vapor deposition is performed.

10. The method according to claim 8, wherein in the deposition step, a deposition process by physical vapor deposition is performed.

11. A device manufacturing method comprising a deposition step of performing deposition using a deposition apparatus according to claim 4.
